(19) United States
(12) Patent Application Publication
(10) Pub. No.: US 2010/0182749 A1
(43) Pub. Date: Jul. 22, 2010

(54) Power supply

(76) Inventor: Yen-Wen Su, Taoyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/320,222

(22) Filed: Jan. 22, 2009

(51) Int. Cl. H05K 7/20

(52) U.S. Cl. 361/695; 361/679.48; 361/679.49

(57) ABSTRACT

A power supply includes a power supply casing, a fan module, a PCB module and a power-output element. The power supply casing has a first opening portion and a second opening portion. The fan module passes through the first opening portion in order to detachably combine with the power supply casing. The PCB module is disposed inside the power supply casing, and the PCB module has a PCB (Printed Circuit Board) and a plurality of electronic elements electrically disposed on the PCB. The power-output element is electrically connected to the PCB module in order to output power to supply external electronic device.

### BACKGROUND OF THE INVENTION

1. Field of the Invention

The present invention relates to a power supply, and particularly relates to a power supply having a power supply casing and a detachable fan detachably assembled at the periphery of the power supply casing.

2. Description of Related Art

There are a lot of circuit boards and electronic elements in the housing of a computer. When the computer is operating, the electronic elements on the circuit board in the computer, such as ICs, integrated circuits etc, generate heat so as to increase the temperature of the housing. When the temperature in the housing exceeds the upper limit of the operating temperature of the electronic elements, the electronic elements fail and the computer breaks down. In order to exhaust the heat from the housing via air convection, heat-exhausting holes are formed and fans are installed on the housing. Thereby, heat is exhausted to the outside of the housing via the heat-exhausting holes.

For example, using a power supply, when the fan module has been operated for a period of time, dust accumulates on the fan module and the weight of the fan increases. Consequently, the operating efficiency of the fan module decreases. Furthermore, the fan body breaks down. At this moment, the user needs to open the power supply casing and disassembles many components so as to disassemble the fan module. After the fan module is maintained or replaced, the fan module is assembled in an opposite sequence to the disassembling process. It is very inconvenient for the user.

### SUMMARY OF THE INVENTION

One particular aspect of the present invention is to provide a power supply having a power supply casing and a detachable fan detachably assembled at the periphery of the power supply casing. The detachable fan can be directly assembled on or disassembled from the outside of the power supply casing. The user does not need to disassemble the power supply casing of the power supply so it is easy to maintain or replace the detachable fan.

In order to achieve the above-mentioned aspects, the present invention provides a power supply, including: a power supply casing, a fan module, a PCB module and a power-output element. The power supply casing has a first opening portion and a second opening portion. The fan module passes through the first opening portion in order to detachably combine with the power supply casing. The PCB module is disposed inside the power supply casing, and the PCB module has a PCB (Printed Circuit Board) and a plurality of electronic elements electrically disposed on the PCB. The power-output element is electrically connected to the PCB module in order to output power to supply external electronic device.

The power supply of the present invention has some advantages, as follows: The present invention allows the fan module to be directly removed from the first opening portion of the power supply casing to maintain or replace the fan module. The user does not need to disassemble the power supply casing or the inner components. It is convenient. When problems occur with the fan module, the user can easily and rapidly assemble or disassemble the fan module so that the problem can be fixed. The problem of lowering the heat-exhausting efficiency due to the dust accumulation is overcome. Therefore, the inner components can operate below their operating temperature. The components are not damaged due to the overheating. The usage life of the device is extended.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objectives and advantages of the present invention will be more readily understood from the following detailed description when read in conjunction with the appended drawings, in which:

FIG. 1A is a partial exploded, cross-sectional, schematic view of a power supply according to the first embodiment of the present invention;

FIG. 1B is an assembled, cross-sectional, schematic view of a power supply according to the first embodiment of the present invention;

FIG. 1C is a top, schematic view of a power supply using first type of external protective net according to the first embodiment of the present invention;

FIG. 1D is a top, schematic view of a power supply using second type of external protective net according to the first embodiment of the present invention;

FIG. 2A is a partial exploded, cross-sectional, schematic view of a power supply according to the second embodiment of the present invention;

FIG. 2B is an assembled, cross-sectional, schematic view of a power supply according to the second embodiment of the present invention;

FIG. 3A is a partial exploded, cross-sectional, schematic view of a power supply according to the third embodiment of the present invention;

FIG. 3B is an assembled, cross-sectional, schematic view of a power supply according to the third embodiment of the present invention;

FIG. 4A is a partial exploded, cross-sectional, schematic view of a power supply according to the fourth embodiment of the present invention;

FIG. 4B is an assembled, cross-sectional, schematic view of a power supply according to the fourth embodiment of the present invention;

FIG. 5A is a partial exploded, cross-sectional, schematic view of a power supply according to the fifth embodiment of the present invention;

FIG. 5B is an assembled, cross-sectional, schematic view of a power supply according to the fifth embodiment of the present invention;

FIG. 6A is a partial exploded, cross-sectional, schematic view of a power supply according to the sixth embodiment of the present invention;

FIG. 6B is an assembled, cross-sectional, schematic view of a power supply according to the sixth embodiment of the present invention;

FIG. 7A is a partial exploded, cross-sectional, schematic view of a power supply according to the seventh embodiment of the present invention; and

FIG. 7B is an assembled, cross-sectional, schematic view of a power supply according to the seventh embodiment of the present invention.

### DETAILED DESCRIPTION OF PREFERRED EMBODIMENTS

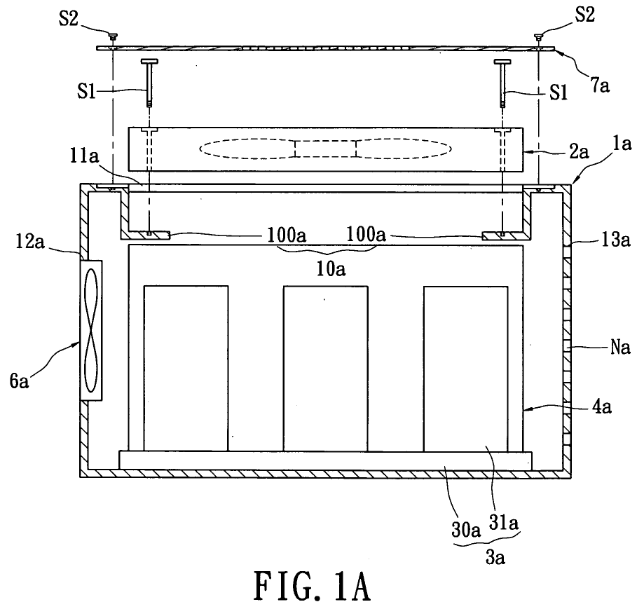

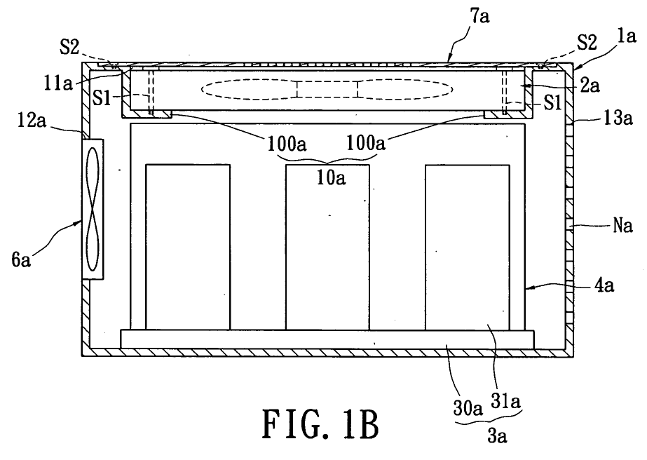

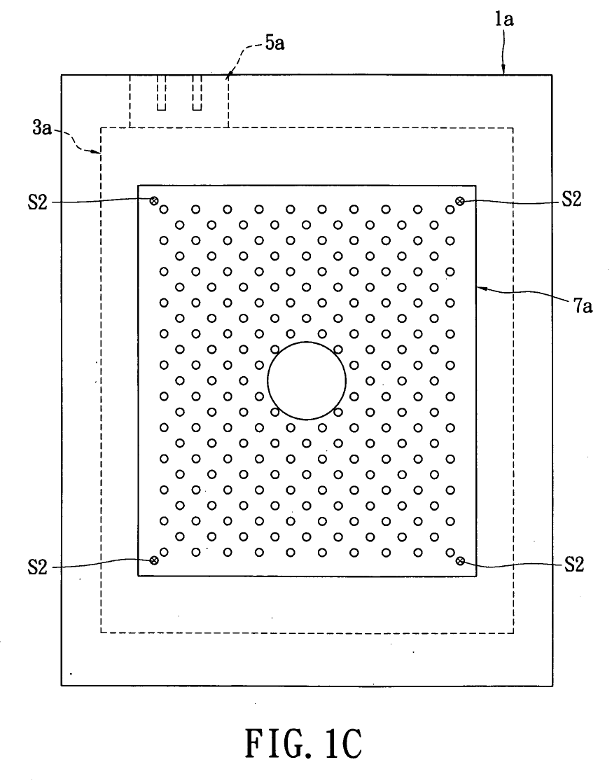

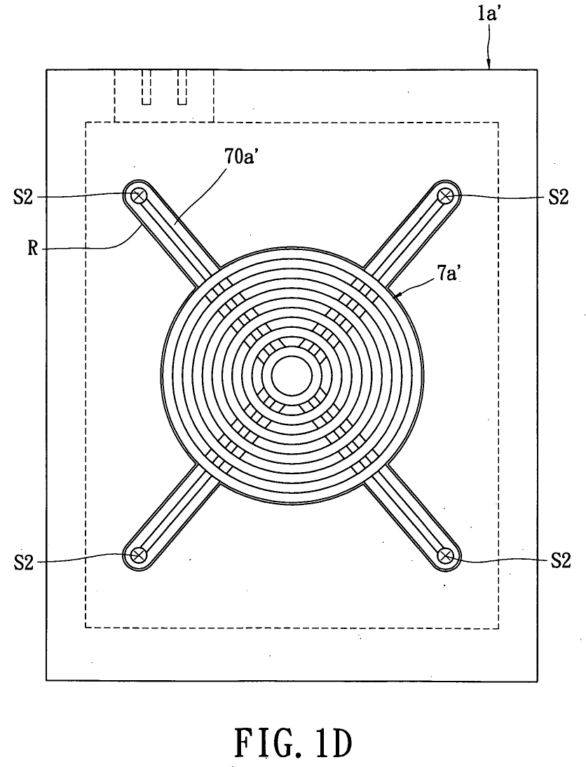

Referring to FIGS. 1A to 1C, the first embodiment of the present invention provides a power supply, including: a power supply casing 1a, a fan module 2a, a PCB module 3a, at least one heat-dissipating element 4a, power-output element 5a, an assistant fan structure 6a and an external protective net 7a.

The power supply casing 1a has a first opening portion 11a and a second opening portion 12a. In the first embodiment, the first opening portion 11a is formed on a top surface of the power supply casing 1a, and the second opening portion 12a is formed on one lateral surface of the power supply casing 1a. Moreover, the assistant fan structure 6a is disposed in the second opening portion 12a. The power supply casing 1a has a third opening portion 13a corresponding to the second opening portion 12a and a meshed structure Na (or a railing structure) detachably or integrally disposed in the third opening portion 13a, and the third opening portion 13a is formed on another lateral surface of the power supply casing 1a. Hence, the first opening portion 11a is a completely open, the assistant fan structure 6a is received in the second opening portion 12a, and the meshed structure Na (or the railing structure) is received in the third opening portion 13a.

However, above-mentioned features of the first opening portion 11a, the second opening portion 12a and the third opening portion 13a do not used to limit the present invention. For example, two meshed structure Na (or two railing structure) can be respectively received in the second opening portion and the third opening portion; Alternatively, the present invention has a first opening portion and a second opening portion only without forming a third opening portion, and an assistant fan structure or a meshed structure (or a railing structure) can be received in the second opening portion. Hence, the power supply casing has a meshed structure or a railing structure that can be detachably or integrally disposed in the second opening portion.

In addition, the power supply casing 1a has a fixing frame 10a disposed under the first opening portion 11a. The fan module 2a passes through the first opening portion 11a and is received in the power supply casing 1a, and the fan module 2a is fixed on the fixing frame 10a by using a plurality of external fixing elements S1. The fixing frame 10a is composed of at least two L-shaped pieces 100a (or an annular piece). The two L-shaped pieces 100a are disposed on an inner surface of the power supply casing 1a. Moreover, the fixing frame 10a can be detachably or integrally disposed on an inner surface of the power supply casing 1a according to different requirements. Hence, the fan module 2a is detachably combined with the power supply casing 1a by using the external fixing elements S1. However, above-mentioned feature of the fixing frame 10a does not use to limit the present invention. Any structure for receiving and fixing the fan module 2a is protected by the present invention.

Furthermore, the external protective net 7a is fixed on an outer surface of the power supply casing 1a by using another a plurality of external fixing elements S2 in order to protect the fan module 2a that is disposed under the first opening portion 11a or prevent the user from being injured by the fan blade of the fan module 2a.

Hence, when a user wants to wash or maintain the fan module 2a, the external protective net 7a needs to be detached by removing the external fixing elements S1 firstly and then the fan module 2a can be detached from the power supply casing 1a by removing the external fixing elements S2.

In addition, the PCB module 3a is disposed inside the power supply casing 1a, and the PCB module 3a has a PCB (Printed Circuit Board) 30a and a plurality of electronic elements 31a electrically disposed on the PCB 30a.

Moreover, the heat-dissipating element 4a is disposed on the PCB module 3a (In other words, the heat-dissipating element 4a can be disposed on the PCB 30a or on the electronic elements 31a) in order to dissipate the heat generated by the PCB module 3a. In addition, the power-output element 5a is electrically connected to the PCB module 3a in order to output power to supply external electronic devices.

Referring to FIG. 1D, the external protective net 7a′ is fixed on an outer surface of the power supply casing 1a′ by using another a plurality of external fixing elements S2. The external protective net 7a′ has a plurality of fixing portions 70a′ extending outwards therefrom, and the power supply casing 1a′ has a plurality of receiving portions R for respectively receiving the fixing portions 70a′. In the first embodiment, the number of the fixing portions 70a′ and the receiving portions R is five.

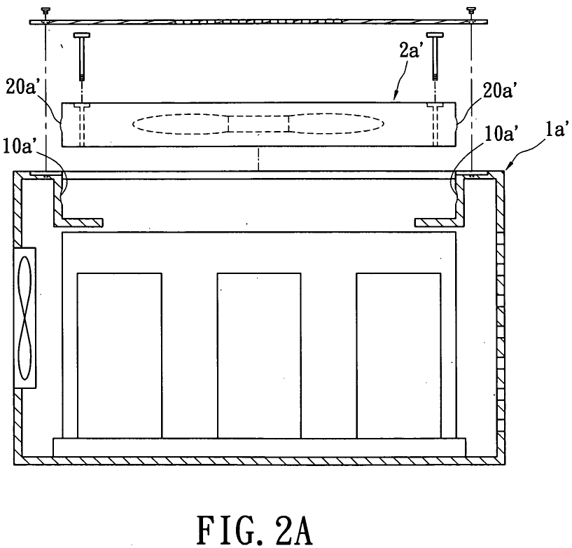

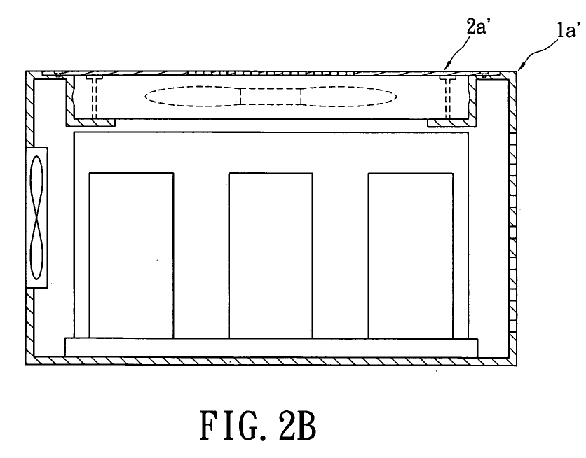

Referring to FIGS. 2A and 2B, the difference between the second embodiment and the first embodiment is that: in the second embodiment, the fan module 2a′ has at least two fan retaining portions 20a′ (two male retaining portions), and the power supply casing 1a′ has at least two casing retaining portions 10a′ (female retaining portions) respectively mated with the at least two fan retaining portions 20a′. In addition, the fan module 2a′ is detachably disposed on an outer surface of the power supply casing 1a′ by matching the two fan retaining portions 20a′ and the two casing retaining portions 10a′.

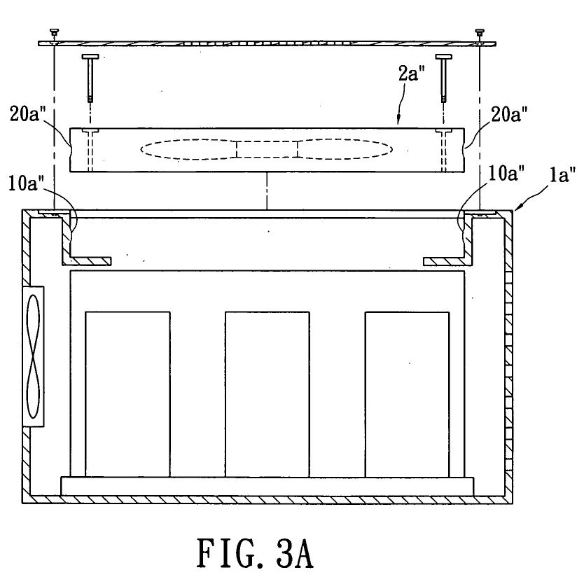

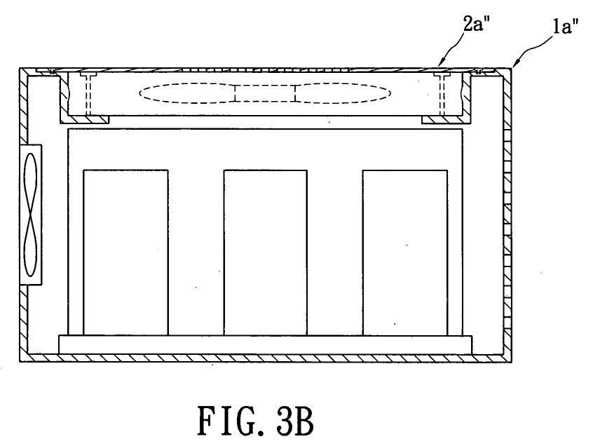

Referring to FIGS. 3A and 3B, the difference between the third embodiment and the second embodiment is that: in the third embodiment, the fan module 2a″ has at least two fan retaining portions 20a″ (two female retaining portions), and the power supply casing 1a″ has at least two casing retaining portions 10a″ (male retaining portions) respectively mated with the at least two fan retaining portions 20a″. In addition, the fan module 2a″ is detachably disposed on an outer surface of the power supply casing 1a″ by matching the two fan retaining portions 20a″ and the two casing retaining portions 10a″.

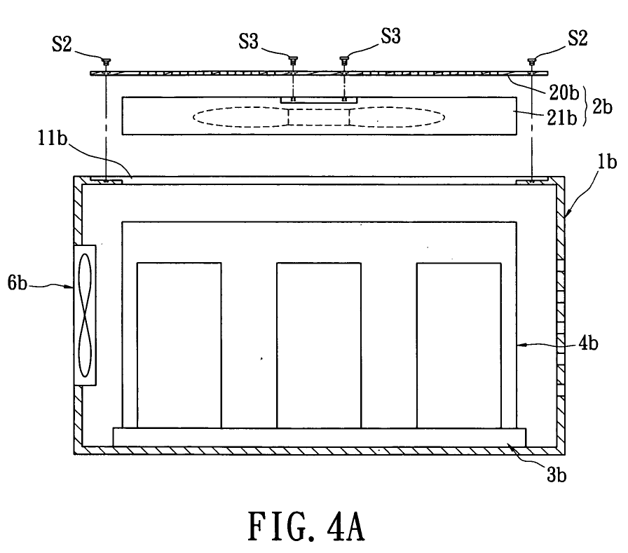

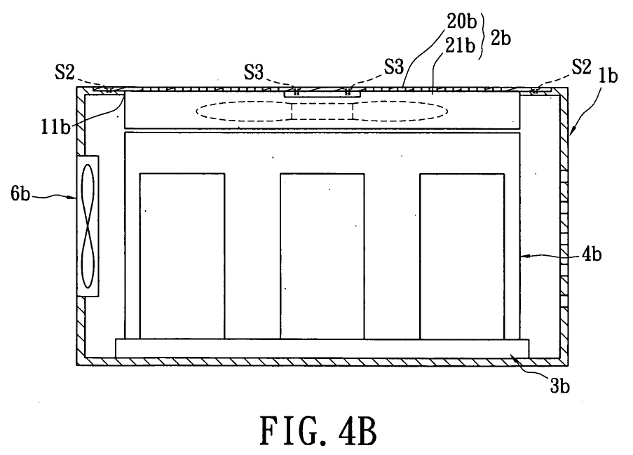

Referring to FIGS. 4A to 4B, the fourth embodiment of the present invention provides a power supply, including: a power supply casing 1b, a fan module 2b, a PCB module 3b, at least one heat-dissipating element 4b, power-output element (not shown), and an assistant fan structure 6b.

The difference between the fourth embodiment and above-mentioned embodiments is that: in the fourth embodiment, the fan module 2b has an external protective net 20b and a fan element 21b disposed under the external protective net 20b by using a plurality of external fixing elements S3. The external protective net 20b is detachably disposed on an outer surface of the power supply casing 1b by using the external fixing elements S2. The fan element 21b passes through the first opening portion 11b in order to be received in the power supply casing 1b, and the fan module 2b is combined with the power supply casing 1b by the external protective net 20b.

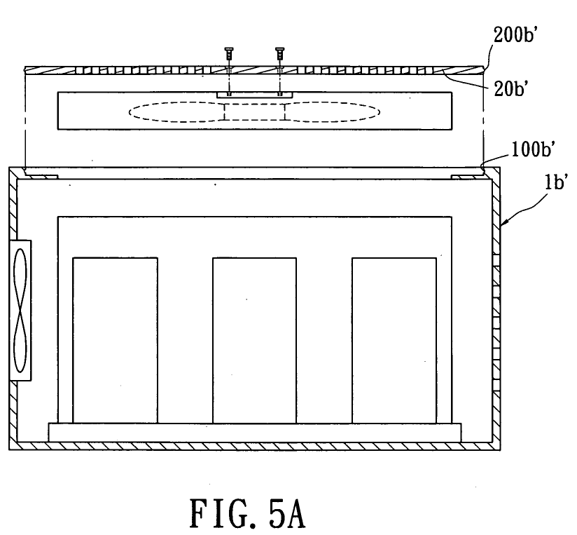

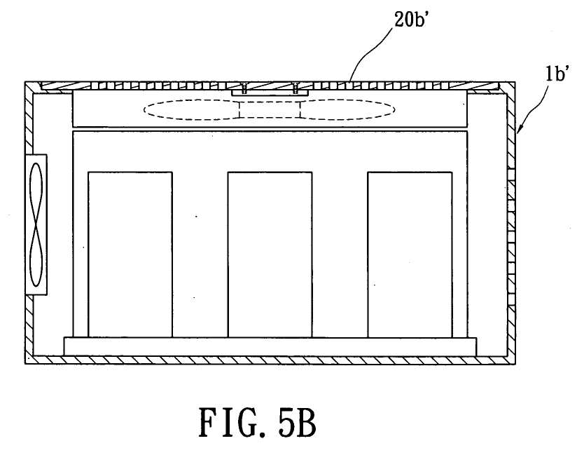

Referring to FIGS. 5A and 5B, the difference between the fifth embodiment and the fourth embodiment is that: in the fifth embodiment, the external protective net 20b′ has at least two net retaining portions 200b′ (two male retaining portions), and the power supply casing 1b′ has at least two casing retaining portions 10b′ (two female retaining portions) respectively mated with the at least two net retaining portions 200b′. The external protective net 20b′ is detachably disposed on an outer surface of the power supply casing 1b′ by matching the two net retaining portions 200b′ and the two casing retaining portions 100b′.

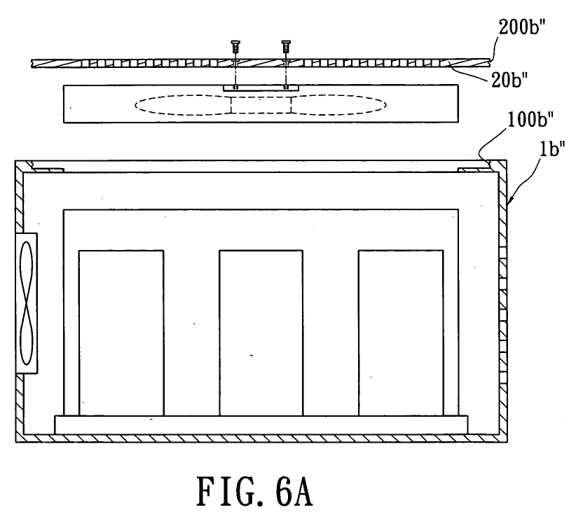

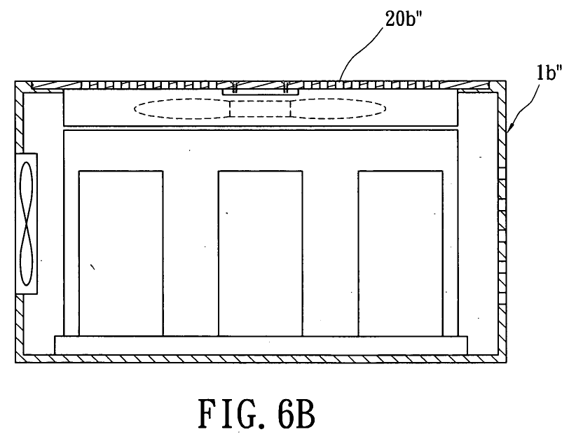

Referring to FIGS. 6A and 6B, the difference between the sixth embodiment and the fifth embodiment is that: in the sixth embodiment, the external protective net 20b″ has at least two net retaining portions 200b″ (two female retaining portions), and the power supply casing 1b″ has at least two casing retaining portions 100b″ (two male retaining portions) respectively mated with the at least two net retaining portions 200b″. The external protective net 20b″ is detachably disposed on an outer surface of the power supply casing 1b″ by matching the two net retaining portions 200b″ and the two casing retaining portions 100b″.

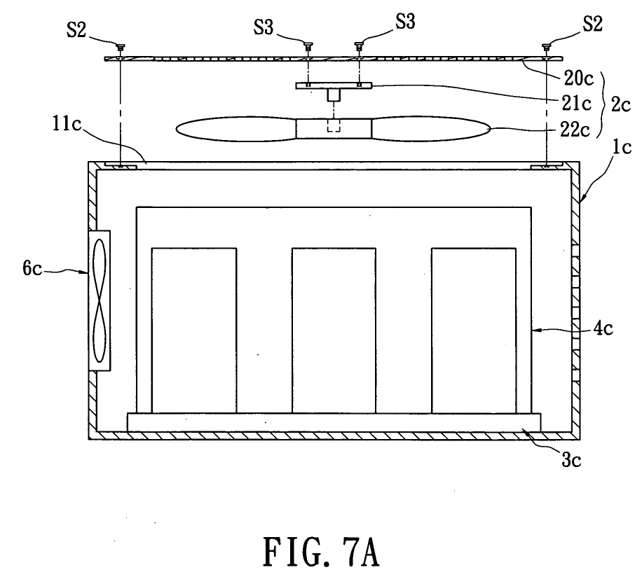

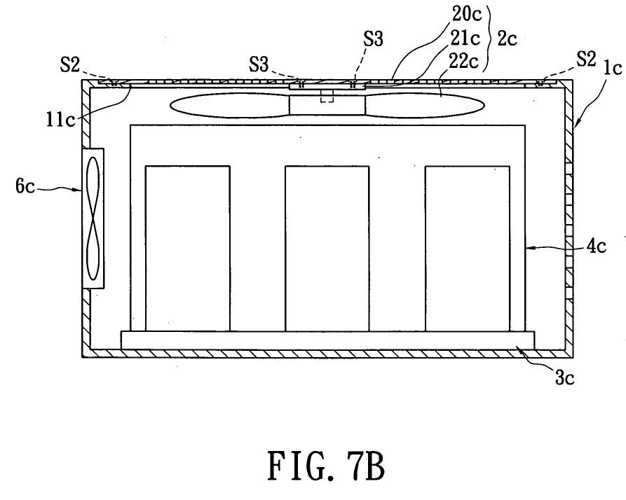

Referring to FIGS. 7A to 7B, the seventh embodiment of the present invention provides a power supply, including: a power supply casing 1c, a fan module 2c, a PCB module 3c, at least one heat-dissipating element 4c, power-output element (not shown), and an assistant fan structure 6c.

The difference between the seventh embodiment and the fourth embodiments is that: in the seventh embodiment, the fan module 2c has an external protective net 20c, a rotating base 21c positioned on a bottom surface of the external protective net 20c by a plurality of external fixing elements S3, and a fan blade 22c rotating on the rotating base 21c. The external protective net 20c is detachably disposed on an outer surface of the power supply casing 1c by using the external fixing elements S2. The fan blade 22c passes through the first opening portion 11c in order to be received in the power supply casing 1c, and the fan module 2c is combined with the power supply casing 1c by the external protective net 20c.

The same as above-mentioned embodiment, the external protective net 20c has at least two net retaining portions, the power supply casing 1c has at least two casing retaining portions respectively mated with the at least two net retaining portions, and the external protective net 20c is detachably disposed on an outer surface of the power supply casing 1c by matching the at least two net retaining portions and the at least two casing retaining portions.

Hence, when a user wants to wash or maintain the fan module 2c, the fan module 2c can be detached directly from the power supply casing 1c by removing the external fixing elements S2.

Although the present invention has been described with reference to the preferred best molds thereof, it will be understood that the present invention is not limited to the details thereof. Various substitutions and modifications have been suggested in the foregoing description, and others will occur to those of ordinary skill in the art. Therefore, all such substitutions and modifications are intended to be embraced within the scope of the present invention as defined in the appended claims.

What is claimed is:

1. A power supply, comprising:
a power supply casing having a first opening portion and a second opening portion;
a fan module passing through the first opening portion in order to detachably combine with the power supply casing;
a PCB module disposed inside the power supply casing, wherein the PCB module has a PCB (Printed Circuit Board) and a plurality of electronic elements electrically disposed on the PCB; and
a power-output element electrically connected to the PCB module in order to output power.

2. The power supply as claimed in claim 1, wherein the first opening portion is formed on a top surface of the power supply casing, and the second opening portion is formed on one lateral surface of the power supply casing.

3. The power supply as claimed in claim 2, wherein the power supply casing has a meshed structure or a railing structure detachably or integrally disposed in the second opening portion.

4. The power supply as claimed in claim 2, further comprising: an assistant fan structure disposed in the second opening portion.

5. The power supply as claimed in claim 2, wherein the power supply casing has a third opening portion corresponding to the second opening portion and a meshed structure or a railing structure detachably or integrally disposed in the third opening portion, and the third opening portion is formed on another lateral surface of the power supply casing.

6. The power supply as claimed in claim 1, further comprising: a plurality of external fixing elements, wherein the fan module is detachably combined with the power supply casing by using the external fixing elements.

7. The power supply as claimed in claim 6, wherein the power supply casing has a fixing frame disposed under the first opening portion, the fan module is received in the power supply casing, and the fan module is fixed on the fixing frame by using the external fixing elements.

8. The power supply as claimed in claim 7, wherein the fixing frame is composed of at least two L-shaped pieces that are disposed on an inner surface of the power supply casing.

9. The power supply as claimed in claim 7, wherein the fixing frame is detachably or integrally disposed on an inner surface of the power supply casing.

10. The power supply as claimed in claim 6, further comprising: an external protective net fixed on an outer surface of the power supply casing by using another a plurality of external fixing elements in order to protect the fan module that is disposed under the first opening portion.

11. The power supply as claimed in claim 100 wherein the external protective net has a plurality of fixing portions extending outwards therefrom, and the power supply casing has a plurality of receiving portions for respectively receiving the fixing portions.

12. The power supply as claimed in claim 6, wherein the fan module has an external protective net, a rotating base positioned on a bottom surface of the external protective net, and a fan blade rotating on the rotating base.

13. The power supply as claimed in claim 12, wherein the external protective net is detachably disposed on an outer surface of the power supply casing by using the external fixing elements, the fan blade passes through the first opening portion in order to be received in the power supply casing, and the fan module is combined with the power supply casing by the external protective net.

14. The power supply as claimed in claim 6, wherein the fan module has an external protective net and a fan element disposed under the external protective net.

15. The power supply as claimed in claim 14, wherein the external protective net is detachably disposed on an outer surface of the power supply casing by using the external fixing elements, the fan element passes through the first opening portion in order to be received in the power supply casing, and the fan module is combined with the power supply casing by the external protective net.

16. The power supply as claimed in claim 1, wherein the fan module has an external protective net, a rotating base positioned on a bottom surface of the external protective net and a fan blade rotating on the rotating base, the external protective net has at least two net retaining portions, the power supply casing has at least two casing retaining portions respectively mated with the at least two net retaining portions, the external protective net is detachably disposed on an outer surface of the power supply casing by matching the at least two net retaining portions and the at least two casing retaining portions, the fan blade passes through the first opening portion in order to be received in the power supply casing, and the fan module is combined with the power supply casing by the external protective net.

17. The power supply as claimed in claim 1, wherein the fan module has an external protective net and a fan element disposed under the external protective net, the external protective net has at least two net retaining portions, the power supply casing has at least two casing retaining portions respectively mated with the at least two net retaining portions, the external protective net is detachably disposed on an outer surface of the power supply casing by matching the at least two net retaining portions and the at least two casing retaining portions, the fan element passes through the first opening portion in order to be received in the power supply casing, and the fan module is combined with the power supply casing by the external protective net.

18. The power supply as claimed in claim 1, wherein the fan module has at least two fan retaining portions, the power supply casing has at least two casing retaining portions respectively mated with the at least two fan retaining portions, and the fan module is detachably disposed on an outer surface of the power supply casing by matching the at least two fan retaining portions and the at least two casing retaining portions.

19. The power supply as claimed in claim 1, further comprising: at least one heat-dissipating element disposed on the PCB module in order to dissipate heat generated by the PCB module.
